(19) United States
(12) Patent Application Publication
(10) Pub. No.: US 2012/0019284 A1
(43) Pub. Date: Jan. 26, 2012

(54) Normally-Off Field Effect Transistor, a Manufacturing Method Therefor and a Method for Programming a Power Field Effect Transistor

(75) Inventors: Anton Mauder, Kolbermoor (DE); Helmut Strack, Munich (DE); Wolfgang Werner, Munich (DE)

(73) Assignee: INFINEON TECHNOLOGIES AUSTRIA AG, Villach (AT)

(21) Appl. No.: 12/843,181

(22) Filed: Jul. 26, 2010

(51) Int. Cl. H03K 19/094; H01L 21/336; H01L 29/792; H01L 29/78

(52) U.S. Cl. 326/49; 257/192; 438/287; 257/314; 257/E29.262; 257/E29.309; 257/E21.409

(57) ABSTRACT

A normally-off power field-effect transistor semiconductor structure is provided. The structure includes a channel, a source electrode, a gate electrode and trapped charges which arranged between the gate electrode and the channel such that the channel is in an off-state when the source electrode and the gate electrode are on the same electric potential. Further, a method for forming a semiconductor device and a method for programming a power field effect transistor are provided.

### FIELD OF THE INVENTION

This specification refers to normally-off field-effect semiconductor devices, in particular to normally-off power field effect transistors, a manufacturing method therefor, and a method for programming a power field effect transistor.

### BACKGROUND

Many functions of modern devices in automotive, consumer and industrial applications such as converting electrical energy and driving an electric motor or an electric machine rely on power semiconductor devices. The importance of power semiconductor devices is steadily increasing, in particular in automotive applications. For example, the energy efficiency of hybrid vehicles, electric vehicles and fuel cell hybrid vehicles depend on the performance of the used power semiconductor devices. For safety reasons, normally-off operating power semiconductor devices are often desirable. With normally-off operating power semiconductor devices the circuitry of electric power devices such as inverters may be simplified and thus the device efficiency increased. Currently, silicon power IGBTs (Insulated Gate Bipolar Transistors) and silicon power MOSFETs are used as normally-off operating devices, but these devices have limitation of performances mainly due to their material property. The so far realized SiC (silicon carbide) normally-off operating power MOSFETs (Metal Oxide Semiconductor Field-Effect Transistors) typically have a relatively high on resistance (Ron) due to the low charge carrier mobility close to the interface between SiC and the widely used gate oxide SiO₂ (silicon dioxide). Therefore, cascode circuits of a normally-off operating low-voltage Si-MOSFET in series with a normally-on operating wide band-gap power semiconductor device such as a SiC-JFET (Junction-FET) or an GaN-MESFET (gallium nitride Metal Semiconductor FET) with high blocking capability are typically used in automotive applications to realize normally-off operation. Dimensioning of these cascode circuits may however be difficult. It is in particular hardly possible to control the switching edges. Further, the low-voltage semiconductor device of the cascode circuit may be driven into an avalanche breakdown during switching off the cascade circuit. Accordingly, there is ongoing need to improve normally-off operating power semiconductor devices, in particular normally-off operating wide band-gap power semiconductor devices.

### BRIEF SUMMARY

According to an embodiment, a power field effect transistor is provided. The power field effect transistor includes a body region of a first conductivity type with a first doping concentration, a channel region of a second conductivity type which forms a pn-junction with the body region, and an insulated gate electrode structure. The insulated gate electrode structure is insulated against the channel region and includes a gate electrode and a layer of trapped charges which is arranged between the gate electrode and the channel region. The charge type of the trapped charges is equal to the charge type of the majority charge carriers of the channel region. The carrier density per area of the trapped charges is equal to or larger than a carrier density obtained by integrating the first doping concentration along a line in the channel region between the body region and the gate electrode structure.

According to an embodiment, a method for forming a semiconductor device is provided. A wafer having a main horizontal surface and a semiconductor layer of a second conductivity type which extends to the main horizontal surface is provided. A first dielectric layer is formed on the main horizontal surface. A second layer is deposited on the dielectric layer. A second dielectric layer is formed on the second layer. A gate electrode is formed on the second dielectric layer. A source electrode is formed in ohmic contact with the semiconductor layer. The semiconductor device is formed such that trapped charges are enclosed between the gate electrode and the semiconductor layer which deplete a channel region in the semiconductor layer next to the gate electrode when the gate electrode and the source electrode are on the same electrical potential.

Those skilled in the art will recognize additional features and advantages upon reading the following detailed description, and upon viewing the accompanying drawings.

### BRIEF DESCRIPTION OF THE SEVERAL VIEWS OF THE DRAWINGS

A full and enabling disclosure of the present invention, including the best mode thereof, to one of ordinary skill in the art, is set forth more particularly in the remainder of the specification, including reference to the accompanying figures. Therein:

FIG. 1 schematically shows a vertical cross-section of a semiconductor device according to one or more embodiments;

FIG. 2 schematically shows a vertical cross-section of a semiconductor device according to one or more embodiments;

FIG. 3 schematically shows a vertical cross-section of a semiconductor device according to one or more embodiments;

FIG. 4 schematically shows a vertical cross-section of a semiconductor device according to one or more embodiments;

FIG. 5 schematically shows a vertical cross-section of a semiconductor device according to one or more embodiments;

FIG. 6 schematically shows a vertical cross-section of a semiconductor device according to one or more embodiments;

FIG. 7 schematically shows a vertical cross-section of a semiconductor device according to one or more embodiments;

FIG. 8 schematically shows a vertical cross-section of a semiconductor device according to one or more embodiments;

FIG. 9 schematically shows a vertical cross-section of a semiconductor device according to one or more embodiments;

FIG. 10 schematically shows a vertical cross-section of a semiconductor device according to one or more embodiments;

FIG. 11 schematically shows a vertical cross-section of a semiconductor device according to one or more embodiments;

FIGS. 12-16 illustrate manufacturing processes according to one or more embodiments;

FIG. 17 illustrates a programming process according to one or more embodiments.

### DETAILED DESCRIPTION

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a first or main surface of a semiconductor substrate or body. This can be for instance the surface of a wafer or a die.

The term “vertical” as used in this specification intends to describe an orientation which is arranged perpendicular to the first surface, i.e. parallel to the normal direction of the first surface of the semiconductor substrate or body.

In this specification, p-doped is referred to as first conductivity type while n-doped is referred to as second conductivity type. It goes without saying that the semiconductor devices can be formed with opposite doping relations so that the first conductivity type can be n-doped and the second conductivity type can be p-doped. Furthermore, some Figures illustrate relative doping concentrations by indicating “−” or “+” next to the doping type. For example, “n⁻” means a doping concentration which is less than the doping concentration of an “n”-doping region while an “n⁺”-doping region has a larger doping concentration than the “n”-doping region. However, indicating the relative doping concentration does not mean that doping regions of the same relative doping concentration have to have the same absolute doping concentration unless otherwise stated. For example, two different n⁺ regions can have different absolute doping concentrations. The same applies, for example, to an n⁺ and a p⁺ region.

Specific embodiments described in this specification pertain to, without being limited thereto, field effect transistors, in particular to power field effect transistors. The term “field-effect” as used in this specification intends to describe the electric field mediated forming of a conductive “channel” and/or control of conductivity and/or shape of the channel in a depleted semiconductor region. The terms “depleted” and “completely depleted” intend to describe that a semiconductor region comprises substantially no free charge carriers. The depleted semiconductor region typically extends through at least a portion of a channel region of a second conductivity type and at least to a pn-junction formed with a semiconductor body region of a first conductivity type. Due to the field-effect, a unipolar current path through the channel region between a source electrode in ohmic contact with the body region and a drain electrode is formed and/or controlled by the electric field. Without applying an external voltage between the gate electrode and the source electrode, the ohmic current path between the source electrode and the drain electrode through the semiconductor device is broken or at least highly ohmic due to at least a depleted portion of the channel region. In the context of the present specification, the term “field-effect structure” intends to describe a structure formed in a semiconductor substrate or semiconductor device having a gate electrode for forming and or shaping a conductive channel in the depleted semiconductor region of a channel region. The gate electrode is at least insulated from the channel region by a dielectric region or dielectric layer. Examples of dielectric materials for forming a dielectric region or dielectric layer between the gate electrode and the body region include, without being limited thereto, SiO₂, Si₃N₄, SiOₓN_{y}, Al₂O₃, ZrO₂, Ta₂O₅, TiO₂ and HfO₂. Without applying external voltages to the field-effect structure, at least a portion of the channel region is completely depleted between the dielectric layer and the body region. The term “power field effect transistor” as used in this specification intends to describe a field effect transistor on a single chip with high voltage and/or high current switching capabilities. In other words, power field effect transistors are intended for high current, typically in the Ampere range, and/or high voltages, typically above 20 V, more typically about 400 V.

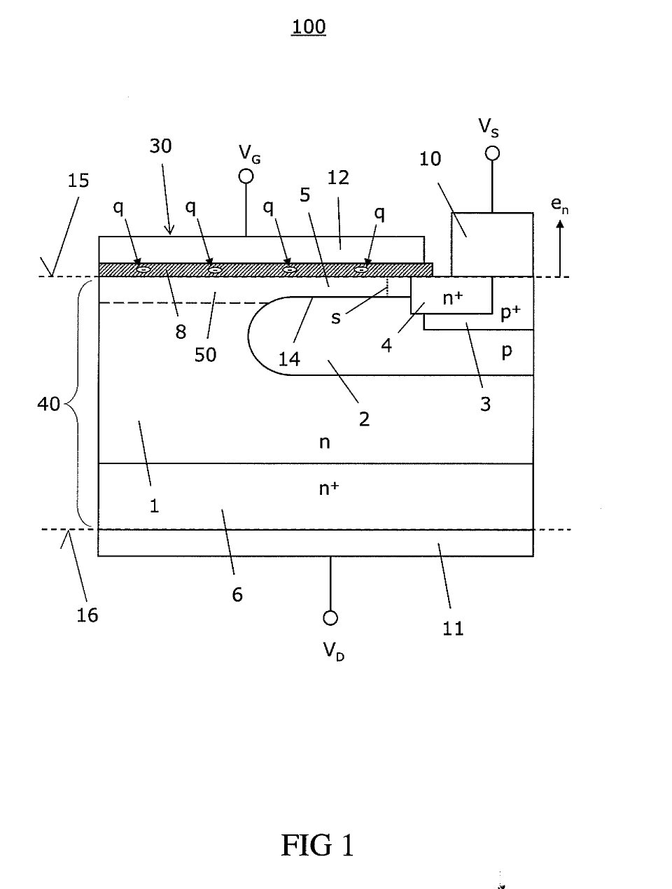

FIG. 1 shows an embodiment of a power semiconductor device 100 in a section of a vertical cross-section. The semiconductor device 100 includes a semiconductor body 40 having a first or main surface 15 and a second surface 16 or back surface 16 arranged opposite to the first surface 15. The normal direction eₙ of the first surface 15 is substantially parallel to, i.e. defines, the vertical direction.

In the following, embodiments pertaining to semiconductor devices and manufacturing methods therefor, respectively, are explained mainly with reference to silicon (Si) semiconductor devices. Accordingly, a monocrystalline semiconductor region or layer is typically a monocrystalline Si-region or Si-layer. It should however be understood that the semiconductor body 40 can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa) or indium gallium arsenide phosphide (InGaAsP), and binary or ternary II-VI semiconductor materials such as cadmium telluride (CdTe) and mercury cadmium telluride (HgCdTe) to name few. The above-mentioned semiconductor materials are also referred to as homojunction semiconductor materials. When combining two different semiconductor materials a heterojunction semiconductor material is formed. Examples of heterojunction semiconductor materials include, without being limited thereto, aluminum gallium nitride (AlGaN) and gallium nitride (GaN) or silicon-silicon carbide (SiₓC₁₋ₓ) and SiGe heterojunction semiconductor material. For power semiconductor applications currently mainly Si, SiC and GaN materials are used. If the semiconductor body comprises a high band gap material such as SiC or GaN which has a high breakdown voltage and high critical avalanche field strength, respectively, the doping of the respective semiconductor regions can be chosen higher which reduces the On-resistance Rₒₙ.

The semiconductor body 40 is typically a wafer 40 or die 40. Typically, semiconductor body 40 includes an embedded p-type body region 2 having a first doping concentration, and an n-type drift region 1 which forms a pn-junction with the body region 2. Between the body region 2 and the first surface 15 an n-type channel region 5 is formed. The channel region adjoins the drift region 1 and forms a pn-junction 14 with the body region 2. A typical length of the channel region is in the range of about 0.75 μm to 3 μm. The drift region 1 is in ohmic contact with a drain electrode 11 on the back side 16 via an optional n⁺-type drift contact layer 6. In the context of the present specification, the terms “in ohmic contact”, “in electric contact”, “in contact”, and “electrically connected” intend to describe that there is an ohmic electric connection or ohmic current path between two regions, portion or parts of a semiconductor devices, in particular a connection of low ohmic resistance, even if no voltages are applied to the semiconductor device. The body region 2 is electrically connected to the source electrode 10 on the main surface 15 via a p⁺-type body contact region 3. The channel region 5 adjoins an n⁺-type source region 4 which is electrically also connected to the source electrode 10. The doping concentrations of the source region 4 and the body contact region are typically higher than the doping concentration of the channel region 5 and the first doping concentration, respectively.

Furthermore, an insulated gate electrode structure 30 is arranged on the first surface 15 and adjoins the channel region 5. Thus, semiconductor device 100 may be operated as a vertical field effect transistor 100, typically as a vertical power field effect transistor. Accordingly, semiconductor device 100 typically includes a plurality of cells each of which corresponds to a structure as shown in FIG. 1. In other words, the semiconductor structure shown in FIG. 1 is typically a unit cell of a power semiconductor device.

Gate electrode structure 30 includes a gate electrode 12 which is insulated against the channel region 5. Gate electrode structure 30 further includes a layer 8 of trapped negative charges q which is arranged between the gate electrode 12 and the channel region 5. For clarity reasons only a few negative charges q are shown in FIG. 1. Layer 8 has a carrier density per area of trapped charges q which may be defined as the integrated carrier density of trapped charges per volume along a line, typically along the shortest line between first surface 15 and gate electrode 12 in layer 8. The carrier density per area of trapped charges q may be constant, at least in sections, or vary in a horizontal direction.

According to an embodiment, the carrier density per area of the trapped charges q is equal to or larger then the first doping concentration integrated along a line s, typically the along the shortest line, in the channel region 5 between the body region 2 and the gate electrode structure 30. Accordingly, a space charge region 50 is formed in the channel region 5 at least between the body region 2 and the gate electrode structure 30 when the body region 2 and the gate electrode 12 are on the same electric potential (V_{S}=V_{G}). The formed space charge region 50 is illustrated by the dashed vertical line and may extend into the drift region 1. In other words, the sign and charge of the trapped charges are chosen such that at least the channel region 5 is completely depleted when the body region 2 and the gate electrode 12 are on the same electric potential. Accordingly, field effect transistor 100 is in the off-state or non-conducting state without a positive bias voltage applied between the gate electrode 12 and the source electrode 10. It goes without saying, that a field effect transistor with inversely doped semiconductor regions and positively trapped charges is in the off-state or non-conducting state without a negative bias voltage applied between the gate electrode 12 and the source electrode 10. In other words, the field effect transistor 100 is normally-off semiconductor device, typically a normally-off power semiconductor device. Thus, field effect transistor 100 may replace a cascode circuit of a normally-off operating low-power Si-MOSFET in series with a normally-on wide band-gap JFET in automotive applications. Accordingly, the circuitry may be simplified and any difficulties arising from capacitances of the high power and the low power semiconductor device in the cascode circuitry may be avoided. In the context of the present specification, the terms “normally-off semiconductor device” and “normally-off operating semiconductor device” intend to describe a semiconductor device in which no or only a comparatively small drain current flows for normal operating voltages, in particular at zero gate voltage relative to the voltage of the source electrode. It goes without saying that the doping relations shown in FIG. 1 may also be reversed. In this case, positive charges are trapped between the gate electrode 12 and the channel region 5. In other words, the sign of the trapped charges is equal to the sign of the majority charge carriers of the channel region, and the carrier density per area of the trapped charges is equal to or larger then the first doping concentration integrated along a line in the channel region between the body region and the gate electrode structure.

Typically, the absolute value of the carrier density per area is larger than about 10¹¹/cm², more typically larger than about 10¹²/cm². The higher the carrier density per area is, the higher the doping concentration of channel region 5 may be chosen. Accordingly, the on-resistance of the power field effect transistor 100 can be reduced. The upper limit of the carrier density per area is typically given by the charge density per area causing avalanche multiplication in the adjoining semiconductor material. For silicon the upper limit of the carrier density per area is about 2*10¹²/cm². For SiC and GaN the upper limit of the carrier density per area is about 2*10¹³/cm². Thus, wide bandgap semiconductors can achieve a channel conductivity comparable with conventional silicon devices and limited by the maximum tolerable electric field in the gate dielectric for switching. For example, silicon dioxide may be exposed as gate dielectric material to electric field strength of up to about 3 MV/cm which corresponds to a carrier density per area of about 2*10¹³/cm².

Depending on the amount of trapped charges and the doping concentration of channel region 5, applying a positive voltage difference between the gate electrode 12 and the source electrode 10 switches the n-channel field effect transistor 100 into the on-mode or conducting mode in which a low resistive current may flow between the source electrode 10 and the gate electrode 12.

In the embodiment illustrated in FIG. 1, the charges q are trapped in the gate dielectric layer 8 which insulates the gate electrode 12 from the channel region 5. Gate dielectric layer 8 may for example include and/or be made of Al-doped SiO₂ or Cs-doped SiO₂. Negatively charged aluminum doped silicon dioxide may be used for n-channel field effect transistors and positively charged cesium doped silicon dioxide may be used for p-channel field effect transistors to provide normally-off field effect transistors.

The minimum distance between channel region 5 and gate electrode 12 may be larger than about 50 nm or even larger than about 100 nm so that the field effect transistor can operate as a power field effect transistor, i.e. withstand high enough gate control voltages.

According to an embodiment, channel region 5 is made of a wide band-gap semiconductor material such as SiC. Accordingly, the doping of the channel region 5 may be chosen higher compared to e.g. a silicon channel region. Thus, the on-resistance Rₒₙ may be reduced.

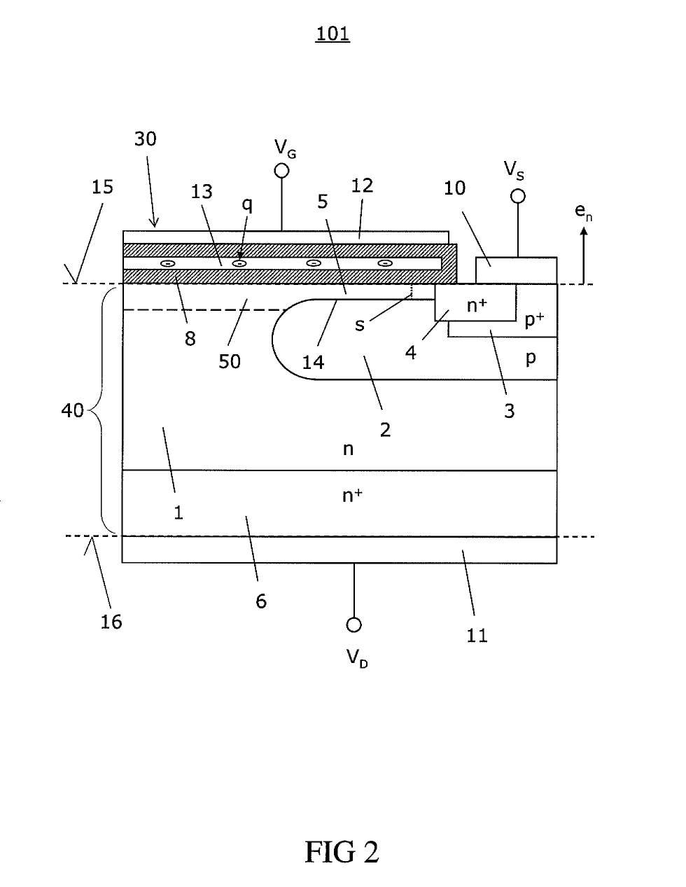

With respect to FIG. 2 further embodiments will be explained. FIG. 2 illustrates a semiconductor device 101 in a section of a vertical cross-section. The semiconductor device 101 of FIG. 2 is similar to the semiconductor device 100 of FIG. 1. However, instead of trapping the charges in the gate dielectric layer, the charged layer is formed by a floating gate electrode 13 charged with trapped charges q in semiconductor device 101. Floating gate electrode 13 is embedded in the gate dielectric layer 8 and arranged between gate electrode 12 and channel region 5. Semiconductor device 101 may also be operated as a normally-off field effect transistor as the carrier density per area of the trapped charges q is equal to or larger than the first doping concentration integrated along the line s in the channel region 5 between the body region 2 and the gate electrode structure 30.

Typically, semiconductor device 101 is a power semiconductor device with a minimum distance between the channel region 5 and the floating gate electrode 30 of more than about 50 nm or even more than 100 nm.

Typically, the absolute value of the carrier density per area is larger than about 10¹¹/cm², more typically larger than 10¹²/cm² or even larger than 2*10¹²/cm². Typically, the total carrier density per area of the gate electrode structure 30 is lower than about 2*10¹²/cm² for a Si-semiconductor device 101 to avoid avalanche breakdown. In this case, higher values for the carrier density per area of the floating gate electrode 13 may be used to overcompensate charges of the opposite sign which may be present in the gate dielectric layer 8. Using a wide bandgap semiconductor like e.g., SiC or GaN allows even higher carrier density per area of the gate electrode structure 30. In this case, a carrier density per area of the gate electrode structure 30 of up to about 2*10¹³/cm² or more may be used due to the higher critical electric field in these materials.

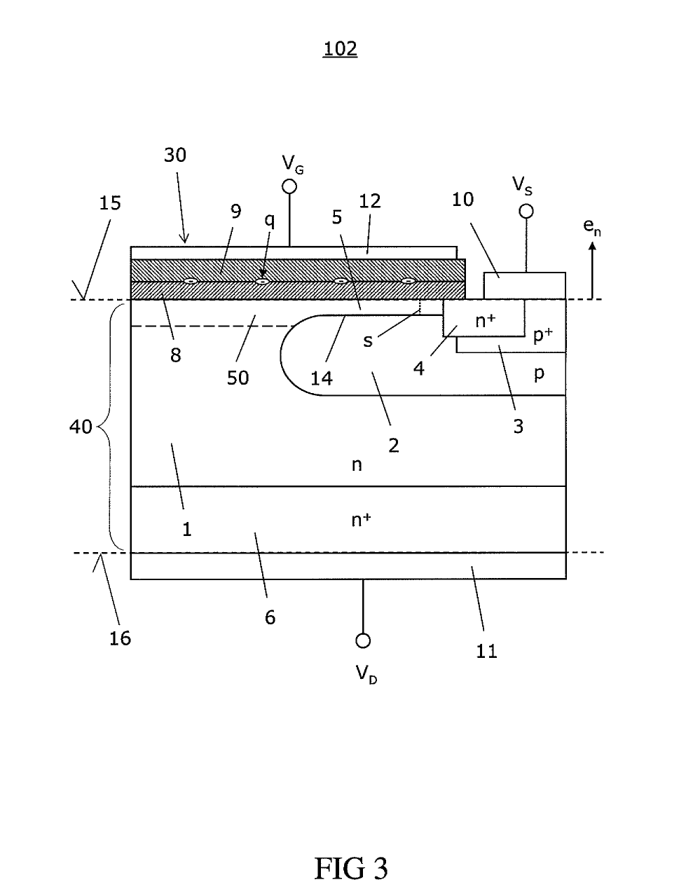

FIG. 3 shows an embodiment of a semiconductor device 102 in a section of a vertical cross-section. The semiconductor device 102 of FIG. 3 is similar to the semiconductor device 100 and 101 of FIGS. 1 and 2. However, insulated gate electrode structure 30 of semiconductor device 102 includes a stacked gate dielectric layer with trapped charges q arranged therebetween. A first gate dielectric layer 9, e.g. a layer of SiO₂, is arranged between the channel region 5 and the gate electrode 12 and a second gate dielectric layer 8, e.g. a Si₃N₄ layer, is arranged between the channel region 5 and the first gate dielectric layer 9. The charged layer includes an interface formed between with the first and second gate dielectric layer 8, 9. Si₃N₄ has a lower band gap than SiO₂. Accordingly, negative charges are usually trapped in Si₃N₄ at or close to the interface with SiO₂. Semiconductor device 102 has a carrier density per area of the trapped charges q which is equal to or larger then the first doping concentration integrated along line s in the channel region 5 between the body region 2 and the gate electrode structure 30. Accordingly, semiconductor device 102 may also be operated as a vertical normally-off field effect transistor.

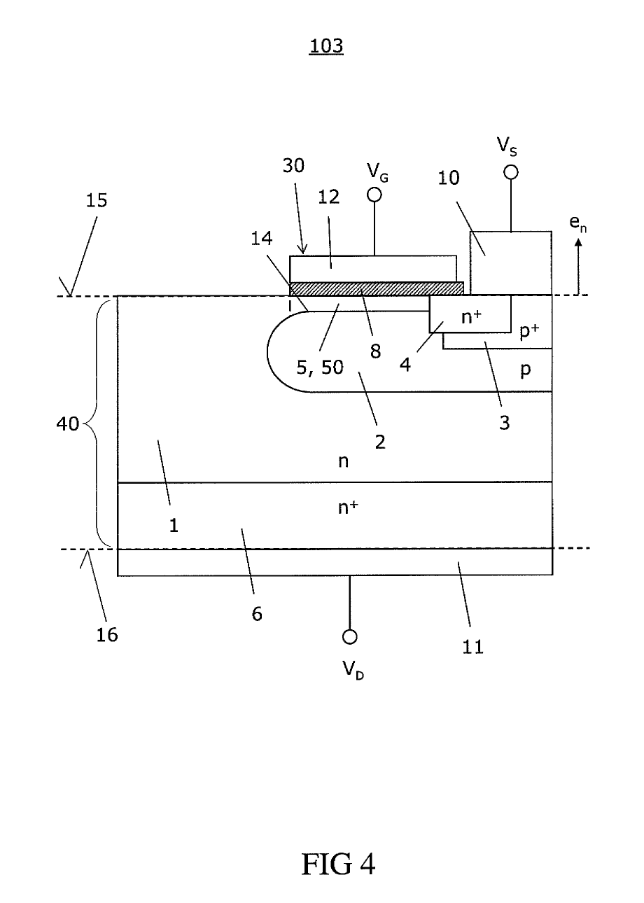

FIG. 4 shows an embodiment of a semiconductor device 103 in a section of a vertical cross-section. The semiconductor device 103 of FIG. 4 is similar to the semiconductor devices 100 to 102 of the previous figures. The gate electrode structure 30 of semiconductor device 103 also includes trapped charges (not shown) such that it can be operated as vertical normally-off field effect transistor. However, the horizontal extension and arrangement of gate electrode structure 30 is chosen such that the space charge region 50 is substantially restricted to the channel region 5 when the gate electrode 12 and the source electrode 10 are on the same electrical potential.

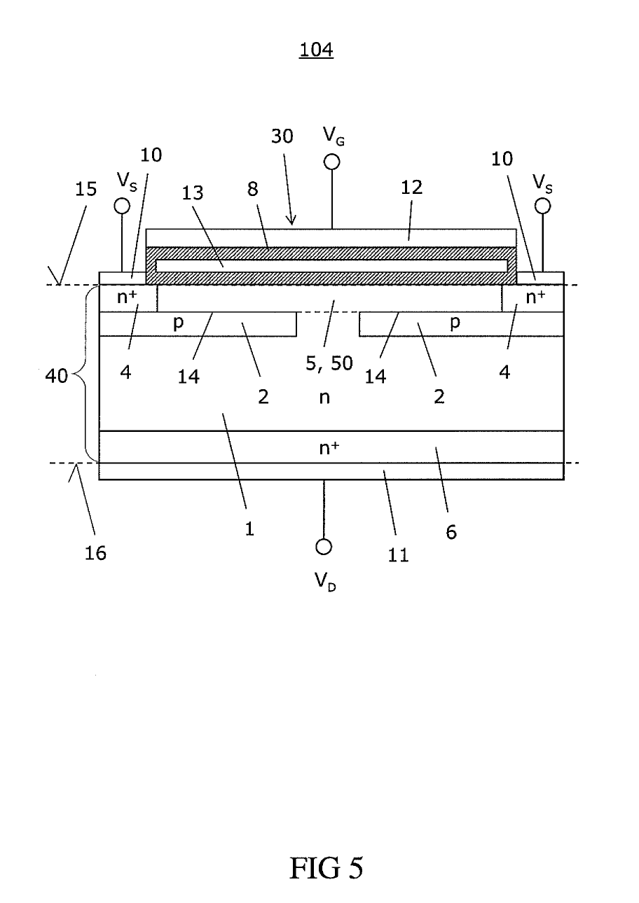

FIG. 5 shows an embodiment of a semiconductor device 104 in a section of a vertical cross-section. The semiconductor device 104 of FIG. 5 is similar to the semiconductor device 101 of FIG. 2. Semiconductor device 104 also includes trapped charges (not shown) in the gate electrode structure 30 such that it can be operated as vertical normally off field effect transistor. In the shown vertical cross-section, one gate electrode structure 30 is arranged above two separated body regions 2. For sake of simplicity, the body contact regions are not shown. The two separated body regions 2 may be bar-shaped and extend in a direction which is perpendicular to the shown cross-section. The two separated body regions 2 may however also correspond to a simply connected ring-shaped body region 2. In this case, the shown two separated source regions 4 also correspond to a simply connected ring-shaped source region 4.

Instead of the shown gate electrode structure 30 with a floating electrode 13, a gate electrode structure with trapped charge in the gate dielectric layer or between two different gate dielectric layers as explained with reference to FIGS. 1 and 3 may be used.

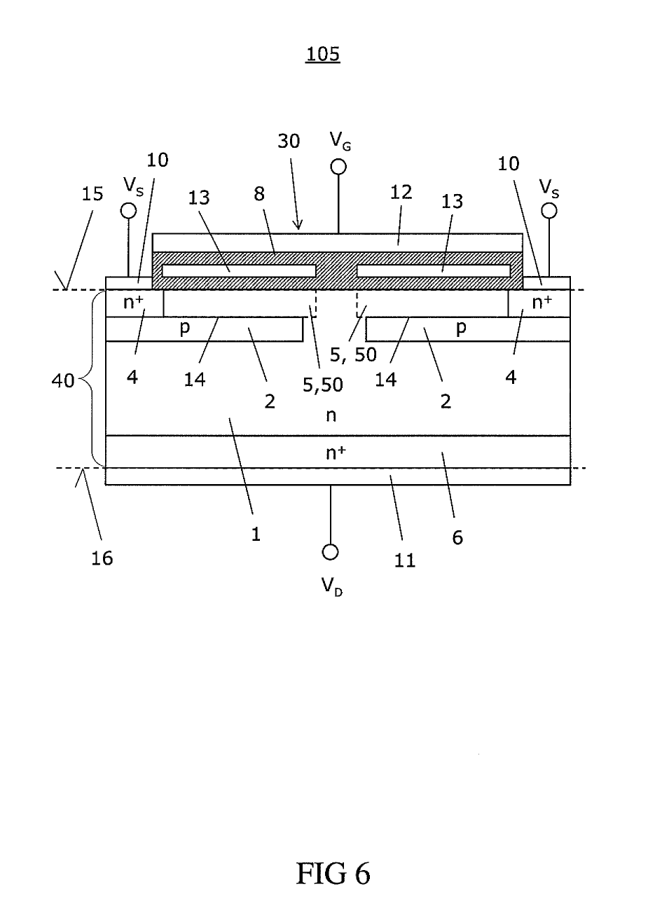

FIG. 6 shows a further embodiment of a semiconductor device 105 in a section of a vertical cross-section. The semiconductor device 105 of FIG. 6 is similar to the semiconductor device 104 of FIG. 5. In the shown vertical cross-section, gate electrode structure 30 has two separated floating gate electrodes 13 which may correspond to a simply connected ring-shaped floating gate electrode 13 or to two bar shaped floating gate electrodes 13.

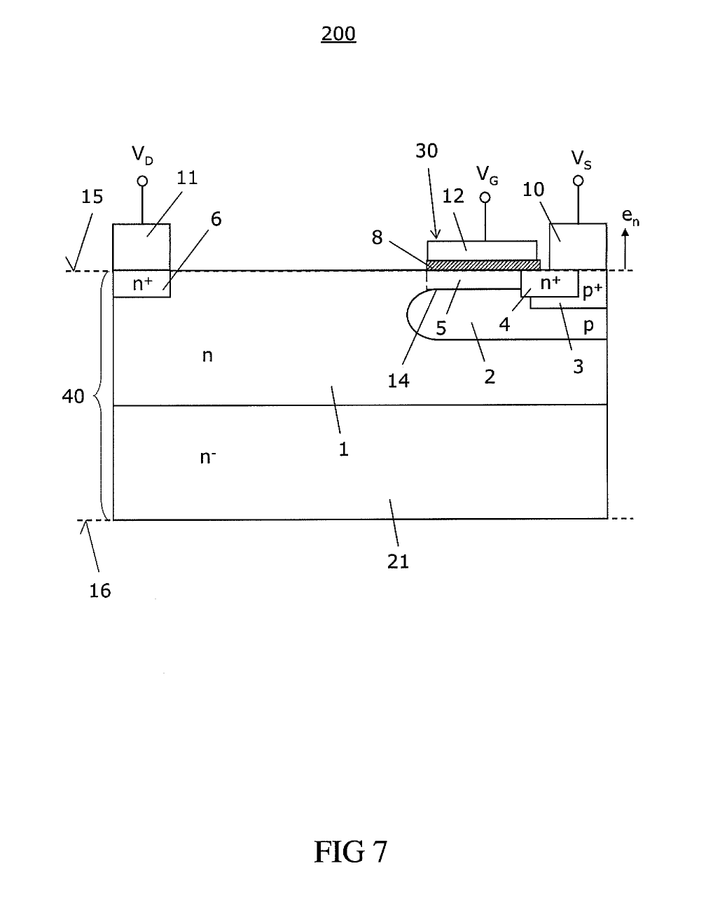

FIG. 7 shows an embodiment of a semiconductor device 200 in a section of a vertical cross-section. The semiconductor device 200 of FIG. 7 is similar to the semiconductor devices 100 to 103 of the FIGS. 1 to 4. However, the drain region 1 is arranged on a common n⁻-type or electrically insulating substrate 21 and the drain electrode 11 of semiconductor device 200 is arranged on the first surface 15. Accordingly, semiconductor device 200 is a lateral power semiconductor device which may be operated as a normally-off n-channel field effect transistor.

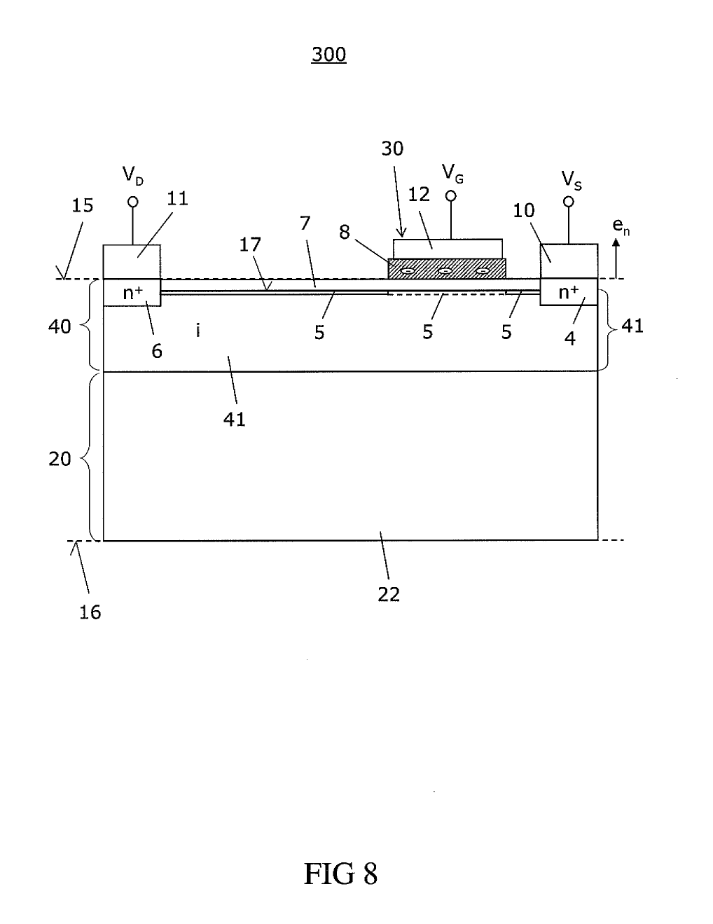

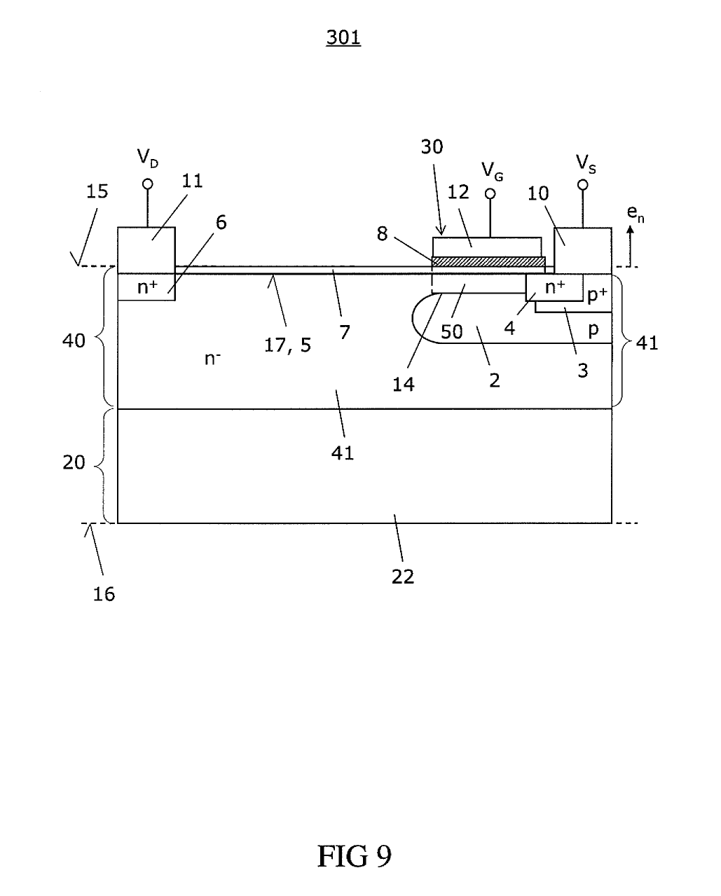

In other words, the semiconductor devices as explained herein are normally-off power field-effect transistor semiconductor structures, typically n-channel field effect transistors, with a channel, a source electrode, a gate electrode and trapped charges. The minimum distance between the channel and the gate electrode is larger than about 50 nm, and the trapped charges are arranged between the gate electrode and the channel such that the channel is in an off-state when the source electrode and the gate electrode are on the same electric potential. The channel may be formed in any semiconductor material, in particular in wide band-gap materials such as SiC or GaN. Further normally-off power field-effect transistors are explained with reference to FIGS. 8 and 9.

FIG. 8 illustrates a semiconductor device 300 in a section of a vertical cross-section. The semiconductor device 300 includes a heterojunction 17 between two materials with different band gaps.

In the semiconductor devices explained with reference to FIGS. 1 to 7, semiconductor regions are doped with impurities which donate mobile charges. The mobile charges are however scattered on the dopants during current conduction. Accordingly, significant ohmic losses may occur. Different thereto, high mobility electrons may be generated at heterojunction 17 when it forms an interface 17 between a doped wide-band gap n-type donor-supply layer 7 and a non-doped or only slightly doped n-type narrow-band gap channel layer or region 41. Accordingly, a two dimensional high mobility electron gas mainly contributes to the current. In other words, semiconductor device 300 may be operated as a HEMT (High Electron Mobility Transistor). HEMTS are also known as heterostructure FETs (HFETs) or modulation-doped FETs (MODFETs). For power semiconductor applications, semiconductor device 300 may include a heterojunction 17 between an undoped GaN layer 41 and an AlGaN layer 7. In another example, heterojunction 17 is formed between a GaAs-layer 41 and a GaAlAs-layer 7.

A quasi two-dimensional channel region 5 is typically formed by the two dimensional electron gas in the gap channel layer or region 41 along the heterojunction 17 and between the source region 4 and the drain region 5. Accordingly, a two-dimensional electron gas may provide a low ohmic current path between the source region 4 and the drain region 5. By providing a gate electrode structure 30 with trapped negative charges, the two-dimensional electron gas may be depleted below the gate dielectric layer 8 as indicated by the dashed vertical line when the source electrode 10 and the gate electrode 12 are on the same potential. Accordingly, semiconductor device 300 may be operated as normally-off field effect transistor.

Typically, semiconductor body 40 is arranged on a common insulator 22. Accordingly, semiconductor device 300 may be fabricated on an SOI-wafer (“Silicon On Insulator”). Alternatively, semiconductor body 40 is arranged on a common substrate. For example, a GaN layer 41 may be arranged on a SiC substrate 22 or other substrates via a not shown thin buffer layer made of an AlN layer and/or AlN—GaN stacked layers.

FIG. 9 illustrates a semiconductor device 301 in a section of a vertical cross-section. The semiconductor device 301 of FIG. 9 also includes a narrow channel region 5 along a heterojunction 17 and may also be operated as normally-off power field effect transistor. However, a p-type body region 2 is in addition embedded in the narrow-band gap channel layer 41. The carrier density of the not shown trapped charges of the gate electrode structure 30 is typically chosen such, that a space charge region 50 is formed which extends from the gate dielectric layer 8 through the narrow channel region 5 at least to the body region 5 when the gate electrode 12 and the source electrode are on same potential. Accordingly, a particularly high resistance in the normally-off state may be achieved.

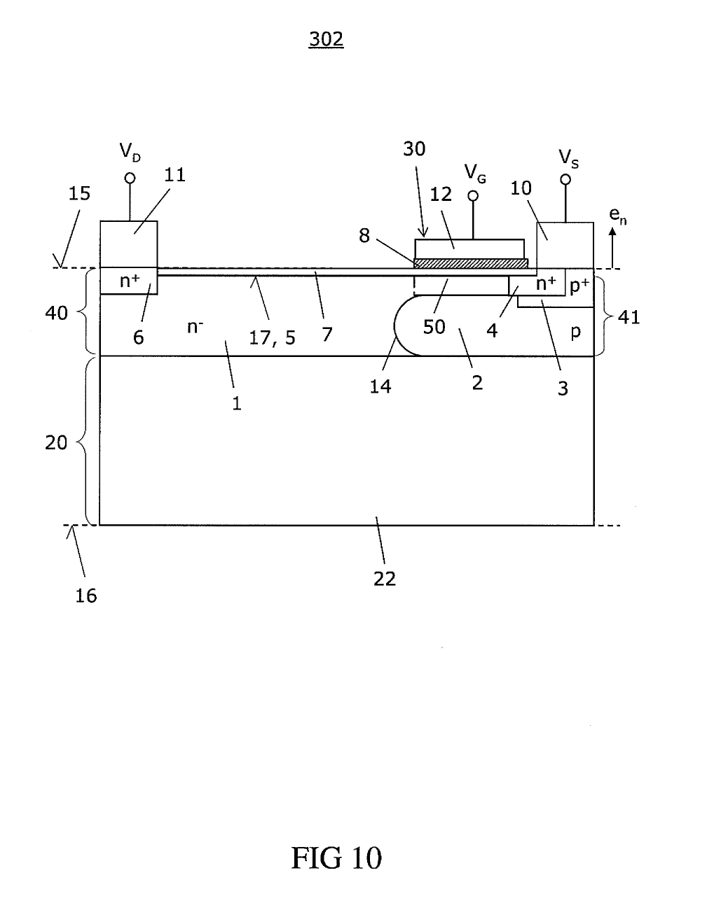

FIG. 10 illustrates a semiconductor device 302 in a section of a vertical cross-section. The semiconductor device 302 of FIG. 10 is similar to the semiconductor device 301 of FIG. 9. It also includes a narrow channel region 5 along a heterojunction 17 and may also be operated as normally-off power field effect transistor. However, the narrow-band gap channel layer 41 of semiconductor device 302 is thinner and the body region 2 extends to the common insulator 22 or common substrate 22. Accordingly, semiconductor material may be saved without significantly changing the device performance.

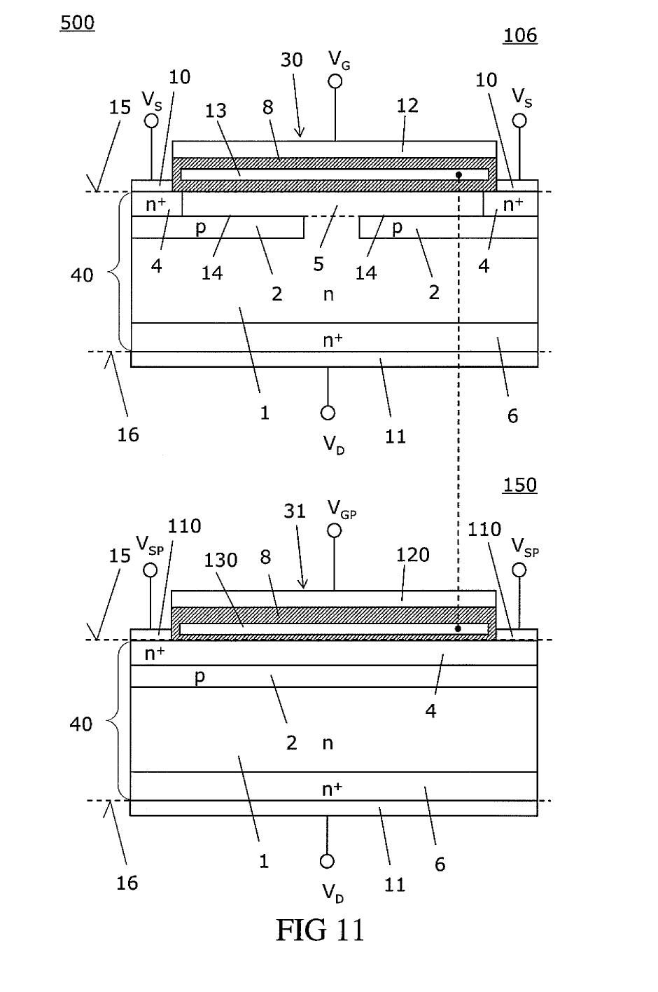

FIG. 11 illustrates a semiconductor device 500 in two different sections of a vertical cross-section. The upper drawing corresponds to a transistor portion of semiconductor device 500, typically to one of a plurality of unit cells of the transistor portion. The lower drawing corresponds to a programming portion of semiconductor device 500. In the exemplary embodiment of FIG. 11, the transistor portion includes a field effect transistor-structure 106 which is similar to the field effect transistor-structure shown in FIG. 5. However, the floating gate electrode 13 of gate electrode structure 30 is not yet charged. Typically, semiconductor structure 106 is a power field effect transistor structure 106 with a minimum distance between the floating gate electrode 13 and the channel region of 50 nm or more. The programming portion includes a programming structure 150 with a gate electrode structure 31. The gate electrode structure 31 is similar to the gate electrode structure 30. However, the minimum distance between the floating gate electrode structure 130 and the source region 4 of programming structure 150 is smaller, e.g. 20 nm. The floating gate electrodes 13 and 130 are in ohmic contact as indicated by the dashed connection. Floating gate electrodes 13, 130 of gate electrode structures 30, 31 may, e.g., be formed as a simple connected structure on semiconductor body 40. Due to the thin gate dielectric layer of programming structure 150, the floating gate electrodes 13, 130 may be charged by a tunneling current, when a positive voltage difference between a gate electrode 120 and a source electrode 110 of programming structure 150 is applied (V_{GP}>V_{SP}). Accordingly, floating gate electrode 13 of power field effect transistor-structure 106 may be charged and recharged (V_{GP}<V_{SP}). Thus, power semiconductor device 500 may be switched from a normally-on semiconductor structure to a normally-off semiconductor structure.

In other words, power semiconductor device 500 includes a semiconductor body 40 with a main horizontal surface 15. Semiconductor body 40 further includes a first semiconductor region 5 of a second conductivity type (n-type) having a first doping concentration and extending to the main horizontal surface 15, a second semiconductor region 2 of a first conductivity type (p-type) which forms a pn-junction 14 with the first semiconductor region 5, and a gate electrode structure 30. The gate electrode structure 30 is arranged on the main horizontal surface 15, and includes a gate electrode 12 and a floating gate electrode 13. The floating gate electrode structure is adapted to be charged such that a space charge region 50 is formed, when the gate electrode 12 is on the same potential as the first and second semiconductor regions 2, 5. The space charge region 50 extends from the main surface 15 at least to the second semiconductor region 4. Typically, power semiconductor device 500 also includes a programming structure which is arranged in another portion and configured to charge floating gate electrode 13 using a tunnel current.

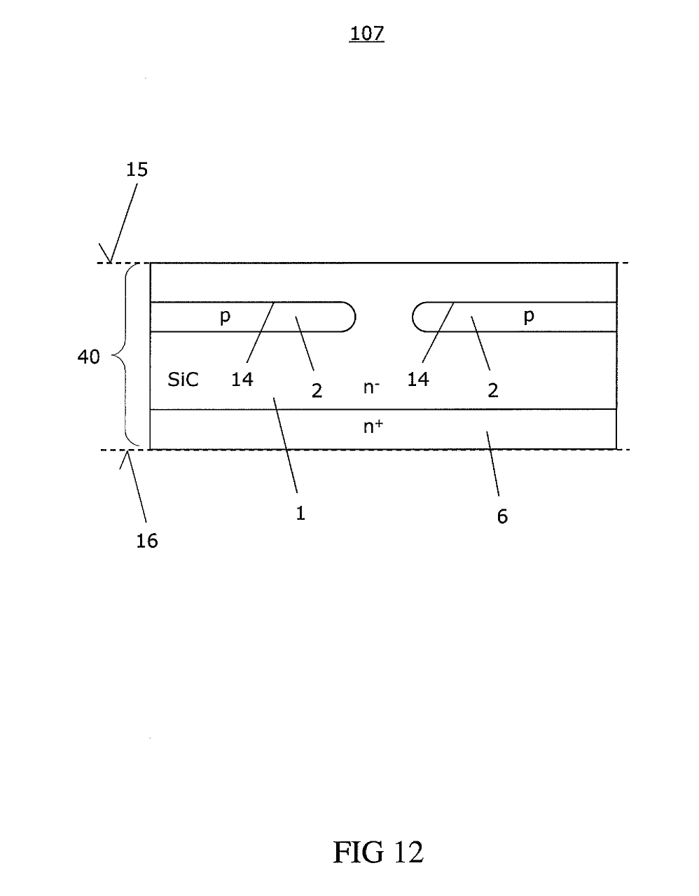

With respect to FIGS. 12 to 16 methods for forming a semiconductor device 100 according to several embodiments are illustrated. In a first process, a wafer or substrate 40 comprising a main horizontal surface and a semiconductor layer 1 of a second conductivity type (n-type) is provided. Semiconductor layer 1 extends to a main or first horizontal surface 15. In the exemplary embodiment of FIG. 12, substrate 40 is made of SiC. Substrate 40 may however be made of any other suitable semiconductor material such as Si or GaN. A heavily doped n⁺-type contact layer may extend from semiconductor layer 1 to a back surface 16 arranged opposite to the main surface 15 to later form an ohmic connection to a drain metallization. Further, substrate 40 may already include embedded body regions 2 of the first conductivity type (p-type). The resulting semiconductor structure 107 is shown in FIG. 12.

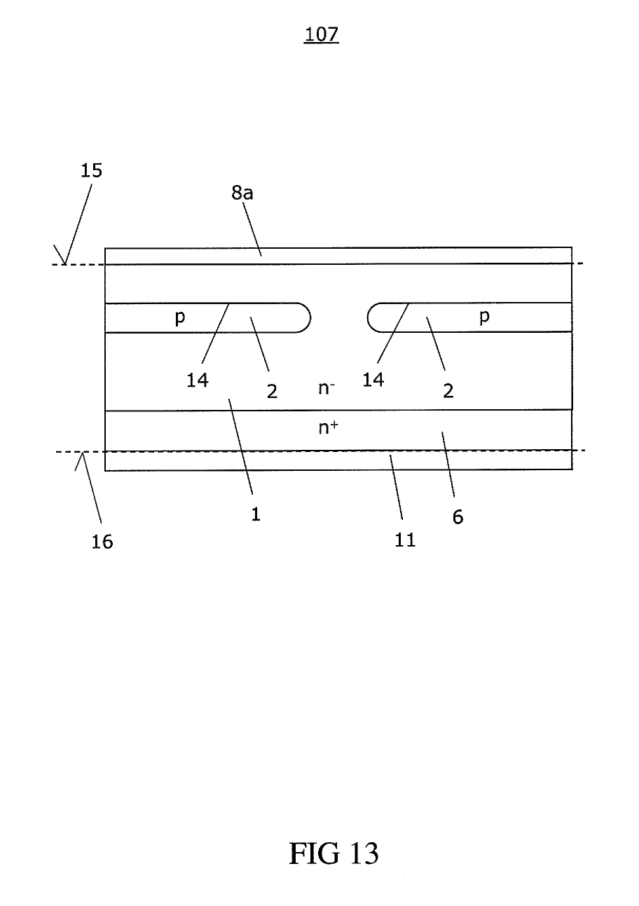

Thereafter, a first dielectric layer 8a is formed on the main horizontal surface 15. Dielectric layer 8a typically includes SiO₂ and may be formed by deposition and/or thermal oxidation. In the case depositing semiconductor body 40 is not made of Si, SiO₂ may be deposited in a CVD (Chemical Vapor Deposition) process. Alternatively, Si may be deposited on the semiconductor body 40 prior to thermally oxidizing. In the case of a Si-semiconductor body 40, layer 8a is typically formed by thermal oxidation, but may also be formed by a CVD process. The resulting semiconductor structure 107 is shown in FIG. 13.

In a subsequent process, a second layer 8b is formed on the first dielectric layer 8a. According to an embodiment, second layer 8b is formed by atomic layer deposition (ALD). The thickness of layer 8b depends on the amount of charges to be trapped. Typically, less than one molecule or atom layer is deposited in one ALD-shot. One up to several ALD-shots are typically used to form a thin layer 8b.

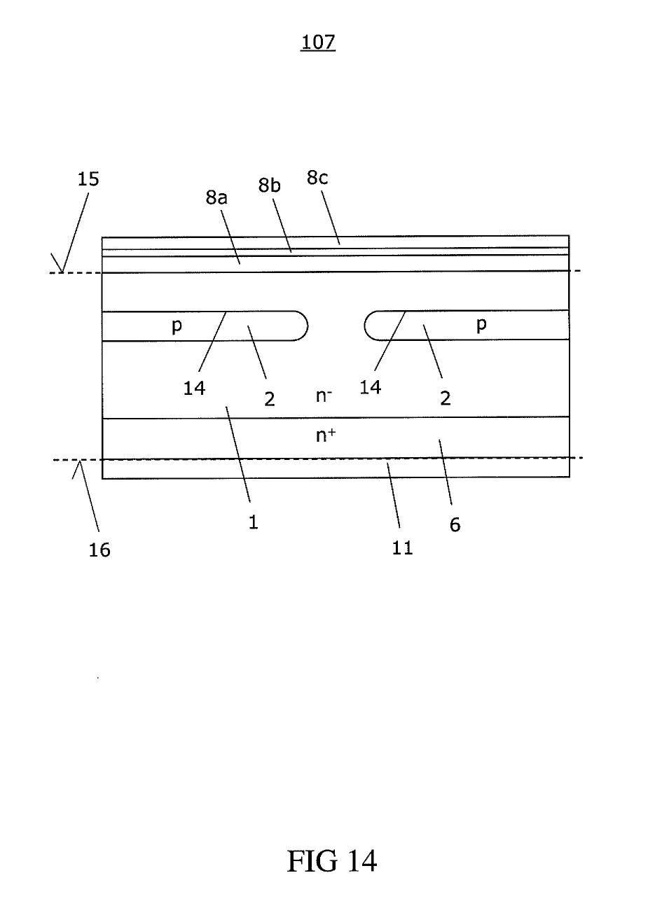

Thereafter, a second dielectric layer 8c, e.g. a SiO₂-layer, is formed on the second layer 8b. The resulting semiconductor structure 107 is shown in FIG. 14.

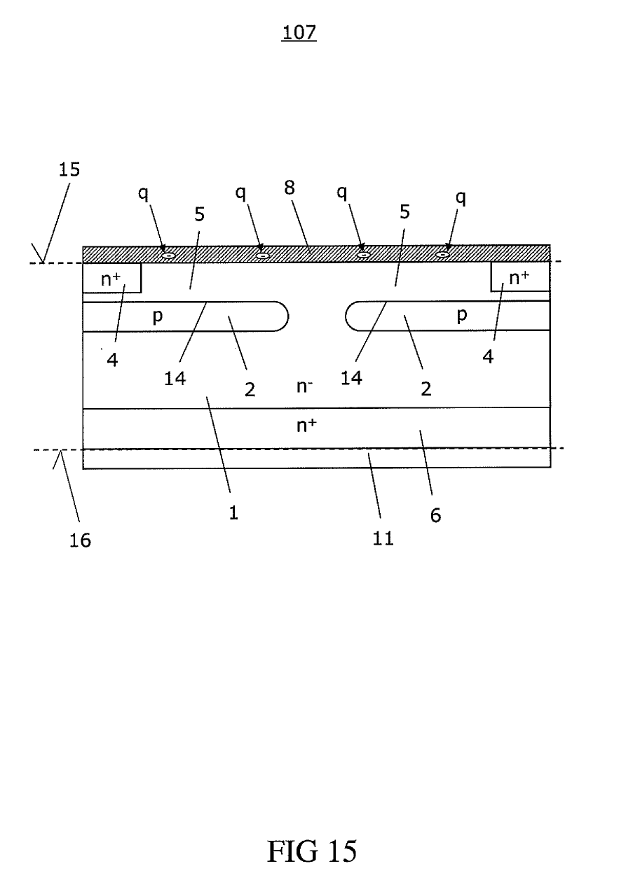

Typically, thermal steps with temperatures from about 700° C. to about 900° C., more typically from about 800° C. to about 900° C. are carried out after depositing layers 8b and 8c. Accordingly, a dielectric layer 8 with trapped charges is formed on the main surface 15 and in contact with layer 1. Depending on the desired charge type, the second layer 8b typically includes aluminum or aluminum oxide for forming a negatively charged layer 8 or cesium or cesium oxide to form a positively charged layer 8. The resulting structure 107 is shown in FIG. 15 which in addition shows source regions 4 of the second conductivity type which may be formed after or prior to forming charged layer 8.

Further, body contact regions (not shown) of the first conductivity type may be formed after or prior to forming charged layer 8. In another embodiment, the body regions 2 are also formed after forming charged layer 8.

Charged layer 8 typically includes an area carrier density of more than about 10¹¹/cm², and more typically of more than about 2*10¹²/cm². Accordingly, a channel region 5 between layer 8 and body region 2 may be depleted by the entrapped charges. The remaining portions of semiconductor layer 1 typically from a drift region 1.

In another embodiment, layers 8a, 8b and 8c form a SiO₂—Si₃N₄—SiO₂-sandwich structure with trapped electrons. In this embodiment, additional thermal annealing steps to form a common layer 8 are typically not carried out.

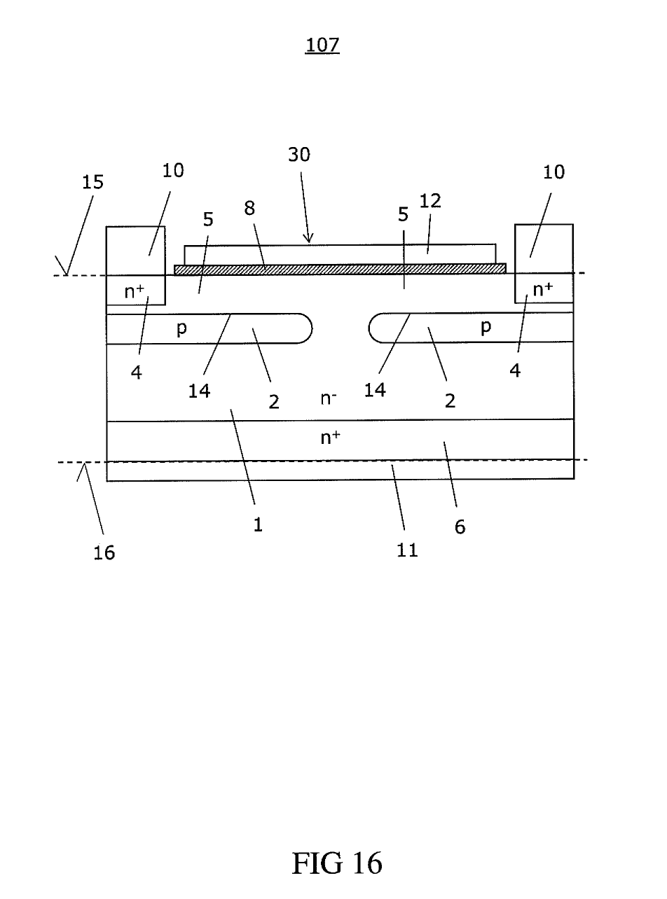

Thereafter, a gate electrode 12 is formed on the second dielectric layer 8c and the second layer 8 respectively, and a source electrode 10 is formed in ohmic contact with the source region 4 and the semiconductor layer 1. The resulting structure 107 is shown in FIG. 16.

According to an embodiment, the manufacturing process is carried out such that trapped charges are enclosed between the gate electrode 12 and the semiconductor layer 1 so that a channel region 5 in the semiconductor layer 1 next to the gate electrode 12 is completely depleted when the gate electrode 12 and the source electrode 10 are on the same electrical potential. In doing so, a normally-off semiconductor device 107, typically a normally-off field effect transistor 107, more typically a normally-off power field effect transistor 107 is manufactured.

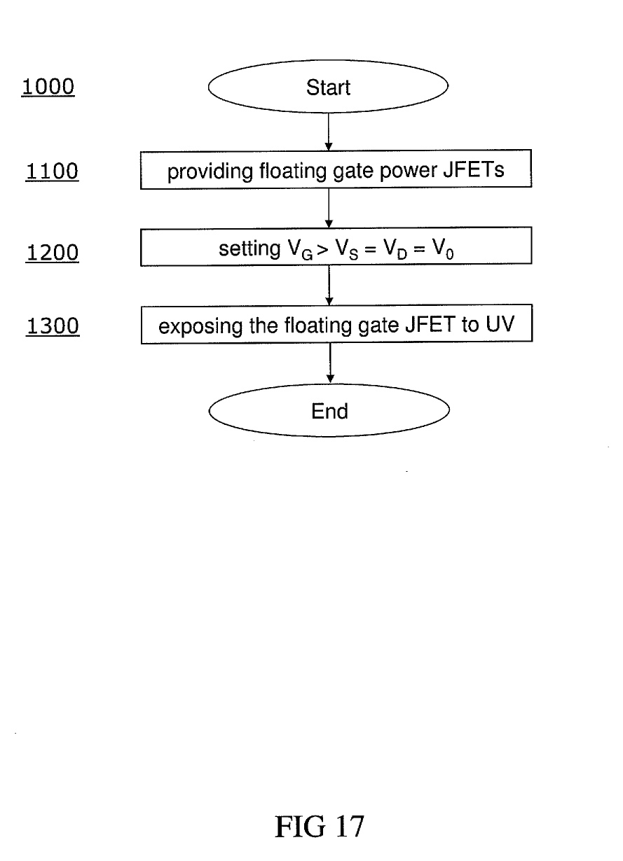

FIG. 17 illustrate a method 1000 for programming a power field effect transistor according to an embodiment. In a first block 1100, one or more floating gate power field effect transistors, typically n-channel field effect transistors, are provided. Thereafter, a positive voltage difference V₀ is set between the voltage V_{G} of the gate electrode(s) and the voltage V_{S} and V_{D} of the source electrode(s) and drain electrode(s) in block 1200 (V_{G}>V_{S}=V_{D}=V₀>0). Subsequently or in parallel, the one or more field effect transistors are exposed to ultraviolet (UV) light, typically UV-C light of e.g. 254 nm, in block 1300.

Due to UV-exposition, electrons of the gate dielectric layer of the one or more power field effect transistors are lifted into the conduction band. Since an electric field is maintained between the channel region and the gate electrode during UV exposition, UV-activated electrons in the gate dielectric layer are collected in the floating gate electrode of the one or more power field effect transistors. Accordingly, the respective floating gate electrodes are negatively charged. The time of UV-exposure mainly depends on the power of the UV-lamp, the amount of charges to be stored in the floating gate electrodes and value of charge carrier density, respectively, to change the one or more field effect transistors from normally-on operating to normally-off operating devices. The exposition time is typically in a range from about 0.1 s to about 10 min strongly depending on the intensity of illumination.

The thickness of the gate dielectric layer between the channel region and the floating gate electrode may be comparatively large, for example larger than 50 nm or even larger than 100 nm. Still, only voltages of a few volts or even below 1 V are required to charge the floating gate electrode. Accordingly, power JEFTs which have typically thicker gate dielectric layers than EPROMS may be programmed as normally-off devices with method 1000. Programming of power field effect transistors with tunneling current instead of UV-supported charging of the floating gate electrodes is typically not feasible, since the required voltages may damage the comparatively thick gate dielectric layer.

Typically, a plurality of power field effect transistors are provided on a lead-frame in block 1000. Accordingly, the respective gate-, source- and drain electrodes are still electrically connected to each other. Thus, a plurality of not yet separated power field effect transistors may programmed by electrically connecting the lead frame in block 1200 and 1300 exposing the lead frame to UV in block 1300. Typically, the electrically connected lead frame lies on a conveyor and passes a UV-lamp in block 1300. This enables a cost efficient programming of power field effect transistors after their manufacture.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A normally-off transistor, comprising a semiconductor body, comprising:
a body region of a first conductivity type comprising a first doping concentration;
a channel region of a second conductivity type forming a pn-junction with the body region;
an insulated gate electrode structure comprising a gate electrode and a layer of trapped charges arranged between the gate electrode and the channel region, the gate electrode being insulated against the channel region; and
wherein a charge type of the trapped charges is equal to a charge type of majority charge carriers of the channel region, and a carrier density per area of the trapped charges is equal to or larger than a carrier density obtained by integrating the first doping concentration along a line in the channel region between the body region and the gate electrode structure.

2. The normally-off transistor of claim 1, wherein an absolute value of the carrier density per area is larger than about 10¹¹/cm².

3. The normally-off transistor of claim 1, wherein a minimum distance between the channel region and the gate electrode is larger than about 50 nm.

4. The normally-off transistor of claim 1, wherein the layer of trapped charges is formed by a floating gate electrode comprising the trapped charges.

5. The normally-off transistor of claim 4, wherein a minimum distance between the channel region and the floating gate electrode is larger than about 50 nm.

6. The normally-off transistor of claim 1, wherein the insulated gate electrode structure comprises a first gate dielectric layer arranged between the channel region and the gate electrode and a second gate dielectric layer arranged between the channel region and the first gate dielectric layer, and wherein the layer of trapped charges is formed along an interface between with the first and second gate dielectric layer.

7. The normally-off transistor of claim 1, wherein the insulated gate electrode structure comprises a gate dielectric layer arranged between the channel region and the gate electrode, the gate dielectric layer comprising at least a portion of the trapped charges.

8. The normally-off transistor of claim 7, wherein the gate dielectric layer comprises silicon dioxide doped with aluminum or cesium.

9. The normally-off transistor of claim 1, wherein the channel region comprises a heterojunction.

10. The normally-off transistor of claim 1, wherein the channel region comprises a wide band-gap semiconductor material.

11. A power semiconductor device, comprising:
semiconductor body, comprising:
a main horizontal surface;
a first semiconductor region of a second conductivity type comprising a first doping concentration and extending to the main horizontal surface;
a second semiconductor region of a first conductivity type forming a pn-junction with the first semiconductor region; and
a gate electrode structure arranged on the main horizontal surface, comprising a gate electrode and being configured to comprise trapped charges such that a space charge region is formed which extends from the main surface at least to the second semiconductor region when the gate electrode is on the same potential as the first and second semiconductor regions.

12. The power semiconductor device of claim 11, further comprising a source electrode in ohmic contact with the second semiconductor region, wherein the semiconductor body further comprises a third semiconductor region of the second conductivity type in ohmic contact with the source electrode and adjoining the first semiconductor region.

13. A normally-off field-effect transistor semiconductor device, comprising:
source electrode;
drain electrode;
channel region operable to carry an electron current between the source electrode and the drain electrode;
a gate electrode;
trapped negative charges; and
wherein the gate electrode is insulated against the trapped negative charges and the channel region, and the trapped negative charges are arranged between the gate electrode and the channel region such that the channel region is in an off-state when the source electrode and the gate electrode are on the same electric potential.

14. The normally-off field-effect transistor semiconductor device of claim 13, wherein the normally-off field-effect transistor semiconductor device is an n-channel power semiconductor structure, and wherein a minimum distance between the channel and the gate electrode is larger than about 50 nm.

15. The normally-off field-effect transistor semiconductor device of claim 13, wherein the channel is formed at a heterojunction.

16. A method for forming a semiconductor device, comprising:
providing a wafer comprising a main horizontal surface and a semiconductor layer of a second conductivity type extending to the main horizontal surface;
forming a first dielectric layer on the main horizontal surface;
depositing a second layer on the first dielectric layer;
forming a second dielectric layer on the second layer;
forming a gate electrode on the second dielectric layer;
forming a source electrode in ohmic contact with the semiconductor layer; and
wherein trapped charges are enclosed between the gate electrode and the semiconductor layer which deplete a channel region in the semiconductor layer next to the gate electrode when the gate electrode and the source electrode are on the same electrical potential.

17. The method of claim 16, wherein the second layer is formed by atomic layer deposition.

18. The method of claim 16, wherein the first layer comprises silicon oxide, and wherein the second layer comprises at least one of aluminum, aluminum oxide, cesium, cesium oxide, and a nitride doped silicon oxide.

19. The method of claim 16, wherein the trapped charges are formed in a layer having a carrier density per area which is larger than about 10¹¹/cm².

20. The method of claim 16, wherein the wafer further comprises a body region of a first conductivity type which is embedded in the semiconductor layer, and wherein the source electrode is in ohmic contact with the body region.

21. The method of claim 16, wherein the semiconductor layer comprises a wide band-gap semiconductor material.

22. The method of claim 16, wherein forming a first dielectric layer comprises at least one of:
depositing a semiconductor material;
thermally oxidizing; and
depositing a dielectric material.

23. A method for programming a power field-effect transistor, comprising:
providing at least one power field-effect transistor comprising a gate dielectric layer, a gate metallization adjoining the gate dielectric layer, a floating gate embedded in the gate dielectric layer, a source metallization and a drain metallization; and charging the floating gate by:
setting a positive voltage difference between the gate metallization, and a common potential of the source metallization and the drain metallization; and
exposing the at least one power field-effect transistor to ultraviolet light.

24. The method of claim 23, wherein providing at least one power field-effect transistor comprises providing a plurality of power field-effect transistor on a lead-frame.

25. The method of claim 23, wherein the power field-effect transistor comprises a semiconductor body, and wherein a minimum distance between the semiconductor body and the floating gate is larger than about 50 nm.
